(19) United States
(12) Patent Application Publication
(10) Pub. No.: US 2026/0372077 A1
(43) Pub. Date: Nov. 19, 2026

(54) CHIP PACKAGE STRUCTURE AND METHOD FOR FORMING THE SAME

(71) Applicant: Taiwan Semiconductor Manufacturing Company, Ltd., Hsinchu (TW)

(72) Inventors: Chen-Hua YU, Hsinchu City (TW); Cheng-Chieh HSIEH, Tainan (TW); Shih-Chang KU, Taipei City (TW); Tung-Liang SHAO, Hsinchu (TW); Sey-Ping SUN, Hsinchu City (TW)

(73) Assignee: Taiwan Semiconductor Manufacturing Company, Ltd., Hsinchu (TW)

(21) Appl. No.: 19/751,226

(22) Filed: Jul. 23, 2026

Related U.S. Application Data
(62) Division of application No. 18/402,404, filed on Jan. 2, 2024.
(60) Provisional application No. 63/610,057, filed on Dec. 14, 2023.

(51) Int. Cl. H10W 40/22; H10P 74/00; H10W 90/00

(52) U.S. Cl. CPC H10W 40/22; H10P 74/273; H10W 90/00; H10W 90/701; H10W 90/722; H10W 90/724; H10W 90/792

(57) ABSTRACT

A chip package structure is provided. The chip package structure includes a first chip structure. The chip package structure includes a heat-spreading substrate over the first chip structure. The chip package structure includes a second chip structure over the heat-spreading substrate. The second chip structure is electrically connected to the first chip structure through the conductive plug structure, the first thermal conductivity of the substrate is higher than a third thermal conductivity of the second chip structure, and the heat-spreading substrate contacts with the first chip structure and the second chip structure.

### PRIORITY CLAIM AND CROSS-REFERENCE

This Application is a Divisional of U.S. Application No. 18/402,404, filed on Jan. 02, 2024, which claims the benefit of U.S. Provisional Application No. 63/610,057, filed on Dec. 14, 2023, and entitled "CHIP PACKAGE STRUCTURE AND METHOD FOR FORMING THE SAME", the entirety of which are incorporated by reference herein.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, since feature sizes continue to decrease, chips generate more heat. Therefore, it is a challenge to form packages with good heat dissipation performance.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1G are cross-sectional views of various stages of a process for forming a chip package structure, in accordance with some embodiments.

FIG. 2 is a cross-sectional view illustrating a chip package structure, in accordance with some embodiments.

FIG. 3 is a cross-sectional view illustrating a chip package structure, in accordance with some embodiments.

FIG. 4 is a cross-sectional view illustrating a chip package structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Additional features can be added to the chip package structure. Some of the features described below can be replaced or eliminated for different embodiments. Although some embodiments are discussed with operations performed in a particular order, these operations may be performed in another logical order.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

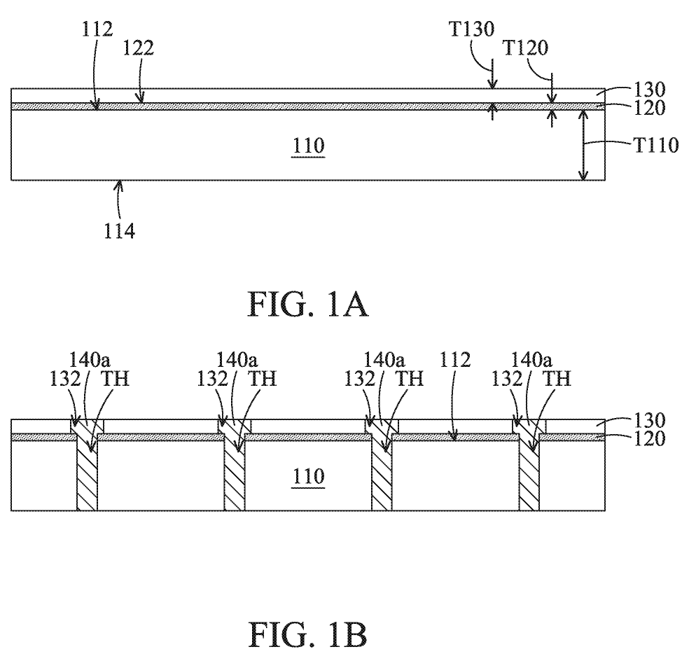

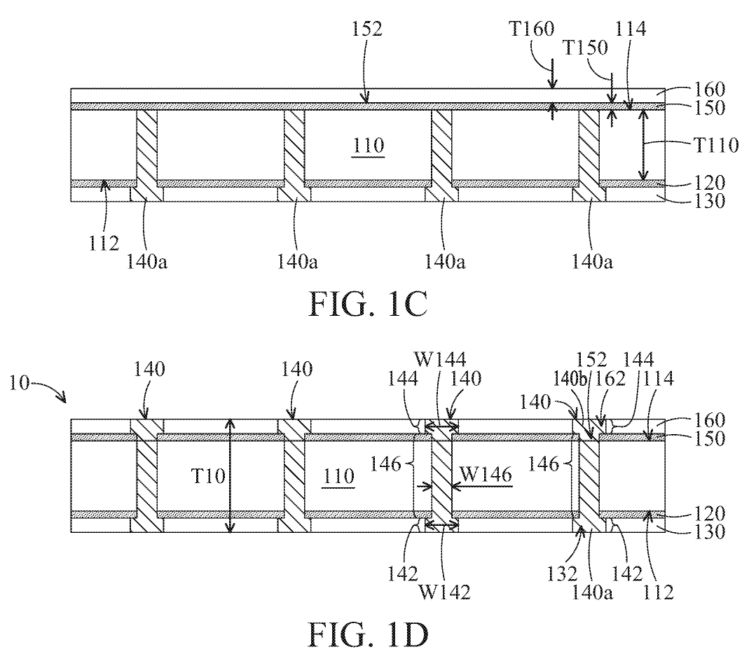

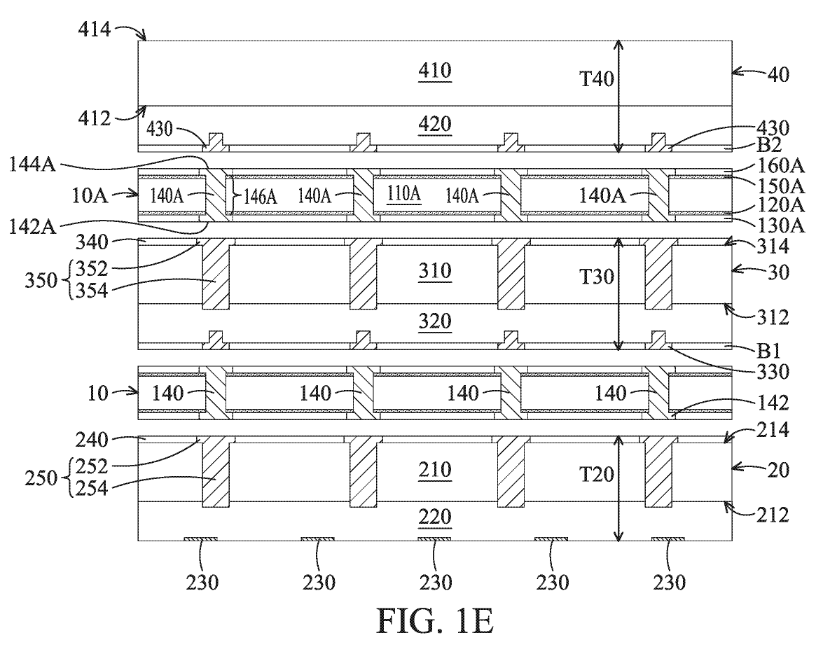

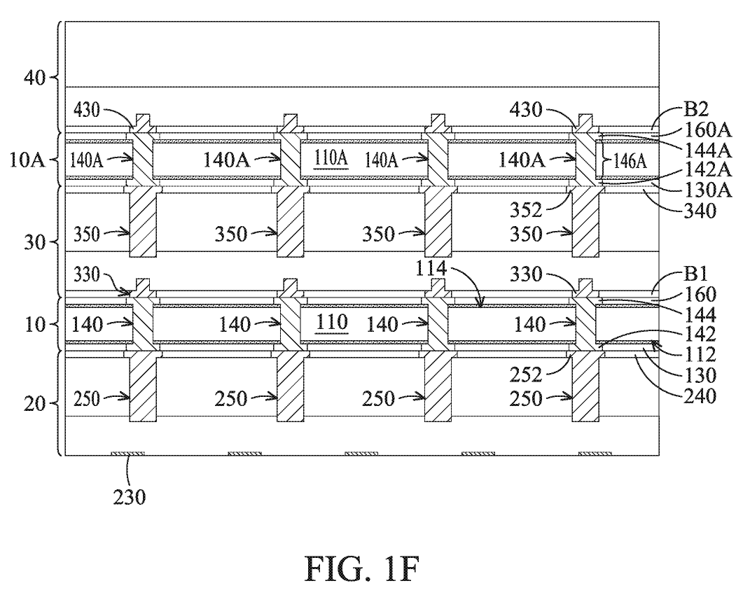

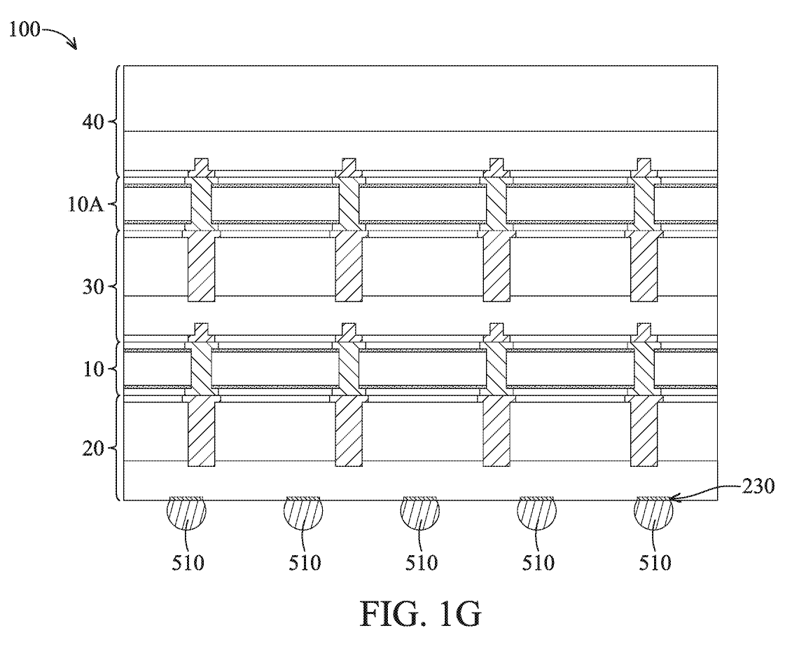

FIGS. 1A-1G are cross-sectional views of various stages of a process for forming a chip package structure, in accordance with some embodiments. As shown in FIG. 1A, a substrate 110 is provided, in accordance with some embodiments. The substrate 110 has opposite surfaces 112 and 114, in accordance with some embodiments. The substrate 110 is made of a dielectric material with a high thermal conductivity, in accordance with some embodiments.

The thermal conductivity of the substrate 110 is greater than about 50 W/(m·K), in accordance with some embodiments. The thermal conductivity of the substrate 110 ranges from about 50 W/(m·K) to about 2000 W/(m·K), in accordance with some embodiments.

The substrate 110 is made of diamond (e.g., single crystalline diamond or nanocrystalline diamond), carbon (e.g., nanocrystalline diamond-like carbon), or a crystalline material (e.g., crystalline BAs or crystalline BeO), in accordance with some embodiments. The substrate 110 has a thickness T110 ranges from about 0.5 μm to about 50 μm, in accordance with some embodiments.

As shown in FIG. 1A, a planarization layer 120 is formed over the surface 112, in accordance with some embodiments. The planarization layer 120 has a surface 122, in accordance with some embodiments. The surface 122 is more planar than the surface 112 of the substrate 110, in accordance with some embodiments. That is, the roughness of the surface 122 is less than that of the surface 112, in accordance with some embodiments. The planarization layer 120 is used to provide a flat surface (e.g., the surface 122) for subsequent processes, in accordance with some embodiments.

The thermal conductivity of the substrate 110 is higher than the thermal conductivity of the planarization layer 120, in accordance with some embodiments. The planarization layer 120 is thinner than the substrate 110, in accordance with some embodiments. The planarization layer 120 has a thickness T120 ranges from about 5 nm to about 5000 nm, in accordance with some embodiments.

The planarization layer 120 is made of a dielectric material such as amorphous silicon, SiN, or SiC, in accordance with some embodiments. The planarization layer 120 and the substrate 110 are made of different materials, in accordance with some embodiments.

As shown in FIG. 1A, a bonding layer 130 is formed over the planarization layer 120, in accordance with some embodiments. The bonding layer 130 is used to be bonded with a chip structure in subsequent processes, in accordance with some embodiments. The thermal conductivity of the substrate 110 is higher than the thermal conductivity of the bonding layer 130, in accordance with some embodiments.

The bonding layer 130 is thinner than the substrate 110, in accordance with some embodiments. The bonding layer 130 has a thickness T130 ranges from about 5 nm to about 5000 nm, in accordance with some embodiments. The bonding layer 130 is made of a dielectric material such as a-Si, SiO, SiON, SiN, SiCN, or AlN, in accordance with some embodiments. The bonding layer 130, the planarization layer 120, and the substrate 110 are made of different materials, in accordance with some embodiments.

As shown in FIG. 1B, the bonding layer 130 is partially removed to form openings 132 in the bonding layer 130, in accordance with some embodiments. The removal process includes a photolithography process and an etching process, in accordance with some embodiments. The etching process includes an anisotropic etching process such as a dry etching process, in accordance with some embodiments.

As shown in FIG. 1B, the substrate 110 and the planarization layer 120 are partially removed to form through holes TH, in accordance with some embodiments. The through holes TH pass through the substrate 110 and the planarization layer 120, in accordance with some embodiments.

The removal process includes a photolithography process and an etching process, in accordance with some embodiments. The etching process includes an anisotropic etching process such as a dry etching process, in accordance with some embodiments.

As shown in FIG. 1B, conductive structures 140a are formed in the openings 132 of the bonding layer 130 and the through holes TH, in accordance with some embodiments. The conductive structures 140a are made of a conductive material such as metal (e.g., titanium, copper, nickel, aluminum, gold, silver, or tungsten) or alloys thereof, in accordance with some embodiments. The conductive structures 140a are formed using a plating process such as an electroplating process, in accordance with some embodiments.

As shown in FIG. 1C, the substrate 110 is flipped upside down, in accordance with some embodiments. As shown in FIG. 1C, a planarization layer 150 is formed over the surface 114 of the substrate 110, in accordance with some embodiments. The planarization layer 150 is has a surface 152, in accordance with some embodiments.

The surface 152 is more planar than the surface 114 of the substrate 110, in accordance with some embodiments. That is, the roughness of the surface 152 is less than that of the surface 114, in accordance with some embodiments. The planarization layer 150 is used to provide a flat surface (e.g., the surface 152) for subsequent processes, in accordance with some embodiments.

The thermal conductivity of the substrate 110 is higher than the thermal conductivity of the planarization layer 150, in accordance with some embodiments. The planarization layer 150 is thinner than the substrate 110, in accordance with some embodiments.

The planarization layer 150 has a thickness T150 ranges from about 5 nm to about 5000 nm, in accordance with some embodiments. The planarization layer 150 is made of a dielectric material such as amorphous silicon, SiN, or SiC, in accordance with some embodiments.

As shown in FIG. 1C, a bonding layer 160 is formed over the planarization layer 150, in accordance with some embodiments. The bonding layer 160 is used to be bonded with a chip structure in subsequent processes, in accordance with some embodiments. The thermal conductivity of the substrate 110 is higher than the thermal conductivity of the bonding layer 160, in accordance with some embodiments.

The bonding layer 160 is thinner than the substrate 110, in accordance with some embodiments. The bonding layer 160 has a thickness T160 ranges from about 5 nm to about 5000 nm, in accordance with some embodiments. The bonding layer 160 is made of a dielectric material such as a-Si, SiO, SiON, SiN, SiCN, or AlN, in accordance with some embodiments. The bonding layer 160, the planarization layer 150, and the substrate 110 are made of different materials, in accordance with some embodiments.

As shown in FIG. 1D, the bonding layer 160 is partially removed to form openings 162 in the bonding layer 160, in accordance with some embodiments. The removal process includes a photolithography process and an etching process, in accordance with some embodiments. The etching process includes an anisotropic etching process such as a dry etching process, in accordance with some embodiments.

As shown in FIG. 1D, the planarization layer 150 is partially removed to form openings 152 in the planarization layer 150, in accordance with some embodiments. The removal process includes a photolithography process and an etching process, in accordance with some embodiments. The etching process includes an anisotropic etching process such as a dry etching process, in accordance with some embodiments.

As shown in FIG. 1D, conductive structures 140b are formed in the openings 162 of the bonding layer 160 and the openings 152 of the planarization layer 150, in accordance with some embodiments. The conductive structures 140b are made of a conductive material such as metal (e.g., titanium, copper, nickel, aluminum, gold, silver, or tungsten) or alloys thereof, in accordance with some embodiments. The conductive structures 140b are formed using a plating process such as an electroplating process, in accordance with some embodiments.

The conductive structure 140a and the conductive structure 140b thereover together form a conductive plug structure 140, in accordance with some embodiments. The substrate 110, the planarization layer 120, the bonding layer 130, the conductive plug structures 140, the planarization layer 150, and the bonding layer 160 together form a heat-spreading substrate 10, in accordance with some embodiments. The thickness T10 of the heat-spreading substrate 10 ranges from about 0.5 μm to about 50 μm, in accordance with some embodiments.

Each conductive plug structure 140 has a bonding pad portion 142, a bonding pad portion 144, and a via portion 146, in accordance with some embodiments. Each bonding pad portion 142 is over the surface 112, in accordance with some embodiments. Each bonding pad portion 142 is in the corresponding opening 132 of the bonding layer 130, in accordance with some embodiments. Each bonding pad portion 142 passes through the bonding layer 130, in accordance with some embodiments.

Each bonding pad portion 144 is over the surface 114, in accordance with some embodiments. Each bonding pad portion 144 is in the corresponding opening 162 of the bonding layer 160, in accordance with some embodiments. Each bonding pad portion 144 passes through the bonding layer 160, in accordance with some embodiments.

Each via portion 146 passes through the substrate 110, in accordance with some embodiments. Each via portion 146 is narrower than the bonding pad portion 142 thereunder, in accordance with some embodiments. That is, the width W146 of each via portion 146 is less than the width W142 of the bonding pad portion 142 thereunder, in accordance with some embodiments.

Each via portion 146 is narrower than the bonding pad portion 144 thereover, in accordance with some embodiments. That is, the width W146 of each via portion 146 is less than the width W144 of the bonding pad portion 144 thereover, in accordance with some embodiments.

As shown in FIG. 1E, chip structures 20, 30, and 40 and a heat-spreading substrate 10A are provided, in accordance with some embodiments. The heat-spreading substrate 10A includes a substrate 110A, a planarization layer 120A, a bonding layer 130A, conductive plug structures 140A, a planarization layer 150A, and a bonding layer 160A, in accordance with some embodiments.

The structures and the materials of the substrate 110A, the planarization layer 120A, the bonding layer 130A, the conductive plug structures 140A, the planarization layer 150A, and the bonding layer 160A are respectively similar to or the same as that of the substrate 110, the planarization layer 120, the bonding layer 130, the conductive plug structures 140, the planarization layer 150, and the bonding layer 160, in accordance with some embodiments.

The relative position between the substrate 110A, the planarization layer 120A, the bonding layer 130A, the conductive plug structures 140A, the planarization layer 150A, and the bonding layer 160A is similar to or the same as that between the substrate 110, the planarization layer 120, the bonding layer 130, the conductive plug structures 140, the planarization layer 150, and the bonding layer 160, in accordance with some embodiments.

In some embodiments, the chip structures 20, 30, and 40 are wafers. In some other embodiments, the chip structures 20, 30, and 40 are chips (or dies). The thickness T20 of the chip structure 20 ranges from about 5 μm to about 800 μm, in accordance with some embodiments. The thickness T30 of the chip structure 30 ranges from about 5 μm to about 800 μm, in accordance with some embodiments. The thickness T40 of the chip structure 40 ranges from about 5 μm to about 800 μm, in accordance with some embodiments.

As shown in FIG. 1E, the chip structure 20 includes a semiconductor substrate 210, devices, an interconnect structure 220, bonding pads 230, a bonding layer 240, and conductive plug structures 250, in accordance with some embodiments.

The semiconductor substrate 210 has a front surface 212 and a back surface 214, in accordance with some embodiments. The devices, the interconnect structure 220, and the bonding pads 230 are formed over the front surface 212 of the semiconductor substrate 210, in accordance with some embodiments. The devices are not shown in figures for the purpose of simplicity and clarity.

The semiconductor substrate 210 is made of an elementary semiconductor material including silicon or germanium in a single crystal structure, a polycrystal structure, or an amorphous structure. In some other embodiments, the semiconductor substrate 210 is made of a compound semiconductor, such as silicon carbide, gallium arsenide, gallium phosphide, indium phosphide, indium arsenide, an alloy semiconductor, such as SiGe, or GaAsP, or a combination thereof. The semiconductor substrate 210 may also include multi-layer semiconductors, semiconductor on insulator (SOI) (such as silicon on insulator or germanium on insulator), or a combination thereof.

In some embodiments, the devices are formed in and/or over the semiconductor substrate 210. Examples of the various devices include active devices, passive devices, other suitable elements, or a combination thereof. The active devices may include transistors or diodes formed at a surface of the semiconductor substrate 210. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the semiconductor substrate 210. The isolation features are used to define active regions and electrically isolate various devices formed in and/or over the semiconductor substrate 210 in the active regions. In some embodiments, the isolation features include shallow trench isolation (STI) features, local oxidation of silicon (LOCOS) features, other suitable isolation features, or a combination thereof.

The interconnect structure 220 is formed over the devices and the semiconductor substrate 210, in accordance with some embodiments. The interconnect structure 220 includes a dielectric layer, wiring layers, and conductive vias, in accordance with some embodiments. The wiring layers and the conductive vias are in the dielectric layer, in accordance with some embodiments. The conductive vias are electrically connected between the wiring layers and the devices, in accordance with some embodiments.

The dielectric layer is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer includes a low-k material or a porous dielectric material having a k-value which is lower than that of silicon oxide, or lower than about 3.0 or about 2.5, in accordance with some embodiments. The wiring layers and the conductive vias are made of a conductive material, such as metal (e.g., copper, aluminum, gold, silver, or tungsten) or alloys thereof, in accordance with some embodiments.

The bonding pads 230 are formed over the interconnect structure 220, in accordance with some embodiments. The bonding pads 230 are electrically connected to the wiring layers and the conductive vias of the interconnect structure 220, in accordance with some embodiments. The bonding pads 230 are made of a conductive material, such as metal (e.g., copper, aluminum, gold, silver, or tungsten) or alloys thereof, in accordance with some embodiments.

The bonding layer 240 is formed over the back surface 214 of the semiconductor substrate 210, in accordance with some embodiments. The bonding layer 240 is made of a dielectric material such as a-Si, SiO, SiON, SiN, SiCN, or AlN, in accordance with some embodiments.

The conductive plug structures 250 pass through the semiconductor substrate 210 and the bonding layer 240, in accordance with some embodiments. The conductive plug structures 250 are electrically connected to the wiring layers and the conductive vias of the interconnect structure 220 and the devices, in accordance with some embodiments.

Each conductive plug structure 250 has a bonding pad portion 252 and a via portion 254, in accordance with some embodiments. The bonding pad portion 252 passes through the bonding layer 240, in accordance with some embodiments. The via portion 254 passes through the semiconductor substrate 210, in accordance with some embodiments.

The conductive plug structures 250 are made of a conductive material such as metal (e.g., titanium, copper, nickel, aluminum, gold, silver, or tungsten) or alloys thereof, in accordance with some embodiments. The conductive plug structures 250 are formed using a plating process such as an electroplating process, in accordance with some embodiments.

As shown in FIG. 1E, the chip structure 30 includes a semiconductor substrate 310, devices, an interconnect structure 320, conductive bonding pads 330, bonding layers B1 and 340, and conductive plug structures 350, in accordance with some embodiments.

The semiconductor substrate 310 has a front surface 312 and a back surface 314, in accordance with some embodiments. The devices, the interconnect structure 320, the bonding layer B1, and the conductive bonding pads 330 are formed over the front surface 312 of the semiconductor substrate 310, in accordance with some embodiments. The devices are not shown in figures for the purpose of simplicity and clarity.

The semiconductor substrate 310 is made of an elementary semiconductor material including silicon or germanium in a single crystal structure, a polycrystal structure, or an amorphous structure. In some other embodiments, the semiconductor substrate 310 is made of a compound semiconductor, such as silicon carbide, gallium arsenide, gallium phosphide, indium phosphide, indium arsenide, an alloy semiconductor, such as SiGe, or GaAsP, or a combination thereof. The semiconductor substrate 310 may also include multi-layer semiconductors, semiconductor on insulator (SOI) (such as silicon on insulator or germanium on insulator), or a combination thereof.

In some embodiments, the devices are formed in and/or over the semiconductor substrate 310. Examples of the various devices include active devices, passive devices, other suitable elements, or a combination thereof. The active devices may include transistors or diodes formed at a surface of the semiconductor substrate 310. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc. Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the semiconductor substrate 310. The isolation features are used to define active regions and electrically isolate various devices formed in and/or over the semiconductor substrate 310 in the active regions. In some embodiments, the isolation features include shallow trench isolation (STI) features, local oxidation of silicon (LOCOS) features, other suitable isolation features, or a combination thereof.

The interconnect structure 320 is formed over the devices and the semiconductor substrate 310, in accordance with some embodiments. The interconnect structure 320 includes a dielectric layer, wiring layers, and conductive vias, in accordance with some embodiments. The wiring layers and the conductive vias are in the dielectric layer, in accordance with some embodiments. The conductive vias are electrically connected between the wiring layers and the devices, in accordance with some embodiments.

The dielectric layer is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer includes a low-k material or a porous dielectric material having a k-value which is lower than that of silicon oxide, or lower than about 3.0 or about 3.5, in accordance with some embodiments. The wiring layers and the conductive vias are made of a conductive material, such as metal (e.g., copper, aluminum, gold, silver, or tungsten) or alloys thereof, in accordance with some embodiments.

The bonding layer B1 is formed over the interconnect structure 320, in accordance with some embodiments. The bonding layer B1 is made of a dielectric material such as a-Si, SiO, SiON, SiN, SiCN, or AlN, in accordance with some embodiments.

The conductive bonding pads 330 are formed in the bonding layer B1 and the interconnect structure 320, in accordance with some embodiments. The conductive bonding pads 330 are electrically connected to the wiring layers and the conductive vias of the interconnect structure 320, in accordance with some embodiments. The conductive bonding pads 330 are made of a conductive material, such as metal (e.g., copper, aluminum, gold, silver, or tungsten) or alloys thereof, in accordance with some embodiments.

The bonding layer 340 is formed over the back surface 314 of the semiconductor substrate 310, in accordance with some embodiments. The conductive plug structures 350 pass through the semiconductor substrate 310 and the bonding layer 340, in accordance with some embodiments. Each conductive plug structure 350 has a bonding pad portion 352 and a via portion 354, in accordance with some embodiments.

The bonding pad portion 352 passes through the bonding layer 340, in accordance with some embodiments. The via portion 354 passes through the semiconductor substrate 310, in accordance with some embodiments. The conductive plug structures 350 are electrically connected to the wiring layers and the conductive vias of the interconnect structure 320 and the devices, in accordance with some embodiments.

The conductive plug structures 350 are made of a conductive material such as metal (e.g., titanium, copper, nickel, aluminum, gold, silver, or tungsten) or alloys thereof, in accordance with some embodiments. The conductive plug structures 350 are formed using a plating process such as an electroplating process, in accordance with some embodiments.

As shown in FIG. 1E, the chip structure 40 includes a semiconductor substrate 410, devices, an interconnect structure 420, a bonding layer B2, and conductive bonding pads 430, in accordance with some embodiments. The semiconductor substrate 410 has a front surface 412 and a back surface 414, in accordance with some embodiments.

The devices, the interconnect structure 420, the bonding layer B2, and the conductive bonding pads 430 are formed over the front surface 412 of the semiconductor substrate 410, in accordance with some embodiments. The devices are not shown in figures for the purpose of simplicity and clarity.

The semiconductor substrate 410 is made of an elementary semiconductor material including silicon or germanium in a single crystal structure, a polycrystal structure, or an amorphous structure. In some other embodiments, the semiconductor substrate 410 is made of a compound semiconductor, such as silicon carbide, gallium arsenide, gallium phosphide, indium phosphide, indium arsenide, an alloy semiconductor, such as SiGe, or GaAsP, or a combination thereof. The semiconductor substrate 410 may also include multi-layer semiconductors, semiconductor on insulator (SOI) (such as silicon on insulator or germanium on insulator), or a combination thereof.

In some embodiments, the devices are formed in and/or over the semiconductor substrate 410. Examples of the various devices include active devices, passive devices, other suitable elements, or a combination thereof. The active devices may include transistors or diodes formed at a surface of the semiconductor substrate 410. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc. Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the semiconductor substrate 410. The isolation features are used to define active regions and electrically isolate various devices formed in and/or over the semiconductor substrate 410 in the active regions. In some embodiments, the isolation features include shallow trench isolation (STI) features, local oxidation of silicon (LOCOS) features, other suitable isolation features, or a combination thereof.

The interconnect structure 420 is formed over the devices and the semiconductor substrate 410, in accordance with some embodiments. The interconnect structure 420 includes a dielectric layer, wiring layers, and conductive vias, in accordance with some embodiments. The wiring layers and the conductive vias are in the dielectric layer, in accordance with some embodiments. The conductive vias are electrically connected between the wiring layers and the devices, in accordance with some embodiments.

The dielectric layer is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer includes a low-k material or a porous dielectric material having a k-value which is lower than that of silicon oxide, or lower than about 4.0 or about 4.5, in accordance with some embodiments. The wiring layers and the conductive vias are made of a conductive material, such as metal (e.g., copper, aluminum, gold, silver, or tungsten) or alloys thereof, in accordance with some embodiments.

The bonding layer B2 is formed over the interconnect structure 420, in accordance with some embodiments. The bonding layer B2 is made of a dielectric material such as a-Si, SiO, SiON, SiN, SiCN, or AlN, in accordance with some embodiments.

The conductive bonding pads 430 are formed in the bonding layer B2, in accordance with some embodiments. The conductive bonding pads 430 are electrically connected to the wiring layers and the conductive vias of the interconnect structure 420, in accordance with some embodiments. The conductive bonding pads 430 are made of a conductive material, such as metal (e.g., copper, aluminum, gold, silver, or tungsten) or alloys thereof, in accordance with some embodiments.

The thermal conductivity of the substrate 110 (or the heat-spreading substrate 10) is higher than the thermal conductivity of the chip structure 20, in accordance with some embodiments. The thermal conductivity of the substrate 110 (or the heat-spreading substrate 10) is higher than the thermal conductivity of the chip structure 30, in accordance with some embodiments.

The thermal conductivity of the substrate 110A (or the heat-spreading substrate 10A) is higher than the thermal conductivity of the chip structure 30, in accordance with some embodiments. The thermal conductivity of the substrate 110A (or the heat-spreading substrate 10A) is higher than the thermal conductivity of the chip structure 40, in accordance with some embodiments.

As shown in FIG. 1F, the heat-spreading substrate 10 is bonded between the chip structures 20 and 30, and the heat-spreading substrate 10A is bonded between the chip structures 30 and 40, in accordance with some embodiments. In some embodiments, the chip structure 20, the heat-spreading substrate 10, the chip structure 30, the heat-spreading substrate 10A, and the chip structure 40 are bonded with each other simultaneously.

The chip structure 30 is electrically connected to the chip structure 20 through the conductive plug structures 140 of the heat-spreading substrate 10, in accordance with some embodiments. The chip structure 40 is electrically connected to the chip structure 30 through the conductive plug structures 140A of the heat-spreading substrate 10A, in accordance with some embodiments.

The heat-spreading substrate 10 is in direct contact with the chip structures 20 and 30, in accordance with some embodiments. The bonding pad portion 142 of the heat-spreading substrate 10 is in direct contact with the corresponding bonding pad portion 252 of the chip structure 20, in accordance with some embodiments. The bonding pad portion 144 of the heat-spreading substrate 10 is in direct contact with the corresponding conductive bonding pad 330 of the chip structure 30, in accordance with some embodiments.

The bonding layer 240 of the chip structure 20 is in direct contact with the bonding layer 130 of the heat-spreading substrate 10, in accordance with some embodiments. The bonding layer B1 of the chip structure 30 is in direct contact with the bonding layer 160 of the heat-spreading substrate 10, in accordance with some embodiments.

The heat-spreading substrate 10A is in direct contact with the chip structures 30 and 40, in accordance with some embodiments. The bonding pad portion 142A of the heat-spreading substrate 10A is in direct contact with the corresponding bonding pad portion 352 of the chip structure 30, in accordance with some embodiments. The bonding pad portion 144A of the heat-spreading substrate 10A is in direct contact with the corresponding conductive bonding pad 430 of the chip structure 40, in accordance with some embodiments.

The bonding layer 340 of the chip structure 30 is in direct contact with the bonding layer 130A of the heat-spreading substrate 10A, in accordance with some embodiments. The bonding layer B2 of the chip structure 40 is in direct contact with the bonding layer 160A of the heat-spreading substrate 10A, in accordance with some embodiments.

As shown in FIG. 1G, conductive bumps 510 are formed on the bonding pads 230 of the chip structure 20, in accordance with some embodiments. The conductive bumps 510 are made of metal or alloys thereof such as tin alloy, in accordance with some embodiments.

If the chip structures 20, 30, and 40 are wafers, a dicing process (or a cutting process) is performed to cut through the chip structures 20, 30, and 40 and the heat-spreading substrates 10 and 10A to form chip package structures 100, in accordance with some embodiments. For the sake of simplicity, FIG. 1G only shows one of the chip package structures 100, in accordance with some embodiments.

When the chip package structures 100 is working, if the heat from the chip structures 20, 30, and 40 accumulates at hot spots, the chip structures 20, 30, and 40 may be damaged by the hot spots, in accordance with some embodiments. Since the thermal conductivity of the heat-spreading substrates 10 and 10A is greater than that of the chip structures 20, 30, and 40, the heat-spreading substrates 10 and 10A can laterally spread the heat from the chip structures 20, 30, and 40, which prevents the heat from accumulating at hot spots, in accordance with some embodiments. Therefore, the reliability and the performance of the chip package structure 100 are improved, in accordance with some embodiments.

Since the application does not change the structure and the materials of the chip structures 20, 30, and 40, the application is compatible with the formation process of the existing chip package structure, in accordance with some embodiments.

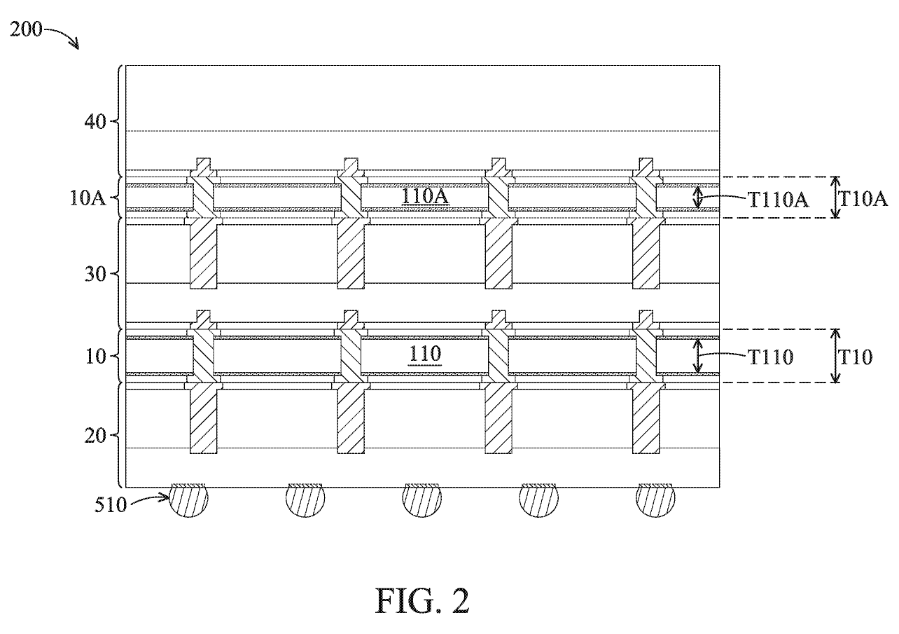

FIG. 2 is a cross-sectional view illustrating a chip package structure 200, in accordance with some embodiments. As shown in FIG. 2, the chip package structure 200 is similar to the chip package structure 100 of FIG. 1G, except that the heat-spreading substrate 10 is thicker than the heat-spreading substrate 10A, in accordance with some embodiments.

The thickness T10 of the heat-spreading substrate 10 is greater than the thickness T10A of the heat-spreading substrate 10A, in accordance with some embodiments. The thickness T110 of the substrate 110 of the heat-spreading substrate 10 is greater than the thickness T110A of the substrate 110A of the heat-spreading substrate 10A, in accordance with some embodiments.

In some embodiments, the heat generation efficiency of the chip structure 20 is higher than that of the chip structure 40. When the chip package structure 200 is working, the chip structure 20 is hotter than the chip structure 40, in accordance with some embodiments.

Since the heat-spreading substrate 10 is thicker, the heat-spreading substrate 10 can more effectively spread the heat from the chip structure 20 laterally, which can effectively reduce the temperature of the chip structure 20, in accordance with some embodiments. Therefore, the temperature of the chip package structure 200 is reduced, which improves the reliability and the performance of the chip package structure 200, in accordance with some embodiments.

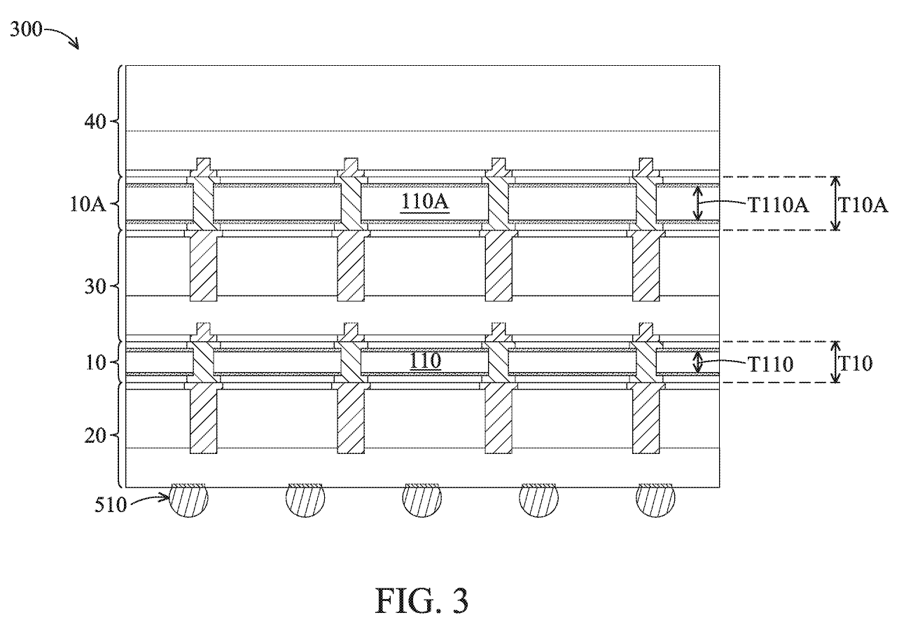

FIG. 3 is a cross-sectional view illustrating a chip package structure 300, in accordance with some embodiments. As shown in FIG. 3, the chip package structure 300 is similar to the chip package structure 100 of FIG. 1G, except that the heat-spreading substrate 10A is thicker than the heat-spreading substrate 10, in accordance with some embodiments.

The thickness T10A of the heat-spreading substrate 10A is greater than the thickness T10 of the heat-spreading substrate 10, in accordance with some embodiments. The thickness T110A of the substrate 110A of the heat-spreading substrate 10A is greater than the thickness T110 of the substrate 110 of the heat-spreading substrate 10, in accordance with some embodiments.

In some embodiments, the heat generation efficiency of the chip structure 40 is higher than that of the chip structure 20. When the chip package structure 300 is working, the chip structure 40 is hotter than the chip structure 20, in accordance with some embodiments.

Since the heat-spreading substrate 10A is thicker, the heat-spreading substrate 10A can more effectively spread the heat from the chip structure 40 laterally, which can effectively reduce the temperature of the chip structure 40, in accordance with some embodiments. Therefore, the temperature of the chip package structure 300 is reduced, which improves the reliability and the performance of the chip package structure 300, in accordance with some embodiments.

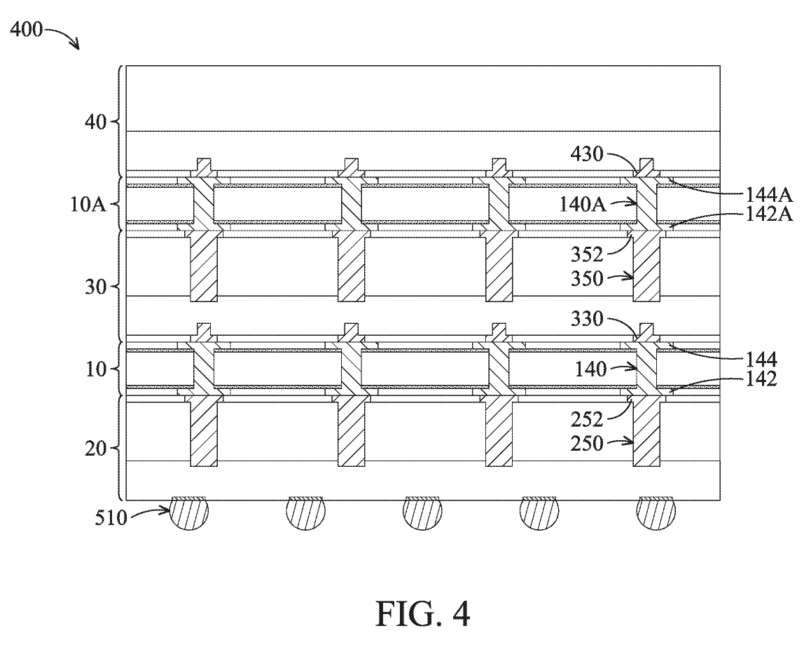

FIG. 4 is a cross-sectional view illustrating a chip package structure 400, in accordance with some embodiments. As shown in FIG. 4, the chip package structure 400 is similar to the chip package structure 100 of FIG. 1G, except that the bonding pad portion 142 of each conductive plug structure 140 is wider than the bonding pad portion 252 of each conductive plug structure 250, and the bonding pad portion 142A of each conductive plug structure 140A is wider than the bonding pad portion 352 of each conductive plug structure 350, in accordance with some embodiments.

The bonding pad portion 144 of each conductive plug structure 140 is wider than the conductive bonding pad 330, in accordance with some embodiments. The bonding pad portion 144A of each conductive plug structure 140A is wider than the conductive bonding pad 430, in accordance with some embodiments.

The heat-spreading substrate 10 does not have devices (including active devices and passive devices) and wiring layers, so there is more space to accommodate the bonding pad portions 142 and 144, in accordance with some embodiments. The (wide) bonding pad portion 142 can improve the yield of the bonding process of the bonding pad portion 142 and the bonding pad portion 252 of the conductive plug structure 250 of the chip structure 20, in accordance with some embodiments. The (wide) bonding pad portion 144 can improve the yield of the bonding process of the bonding pad portion 144 and the conductive bonding pad 330 of the chip structure 30, in accordance with some embodiments.

The heat-spreading substrate 10A does not have devices (including active devices and passive devices) and wiring layers, so there is more space to accommodate the bonding pad portions 142A and 144A, in accordance with some embodiments.

The (wide) bonding pad portion 142A can improve the yield of the bonding process of the bonding pad portion 142A and the bonding pad portion 352 of the conductive plug structure 350 of the chip structure 30, in accordance with some embodiments. The (wide) bonding pad portion 144A can improve the yield of the bonding process of the bonding pad portion 144A and the conductive bonding pad 430 of the chip structure 40, in accordance with some embodiments.

Processes and materials for forming the chip package structures 200, 300, and 400 may be similar to, or the same as, those for forming the chip package structure 100 described above. Elements designated by the same reference numbers as those in FIGS. 1A-4 have structures and materials that are the same or similar. Therefore, the detailed descriptions thereof will not be repeated herein.

In accordance with some embodiments, chip package structures and methods for forming the same are provided. The methods (for forming the chip package structure) form a heat-spreading substrate between two chip structures to laterally spread the heat from the chip structures, which prevents the heat from accumulating at hot spots. Therefore, the reliability and the performance of the chip package structure with the heat-spreading substrate are improved.

In accordance with some embodiments, a chip package structure is provided. The chip package structure includes a first chip structure. The chip package structure includes a heat-spreading substrate over the first chip structure. The heat-spreading substrate includes a substrate and a conductive plug structure, a first thermal conductivity of the substrate is higher than a second thermal conductivity of the first chip structure, the substrate has a first surface and a second surface, the conductive plug structure has a first bonding pad portion, a second bonding pad portion, and a via portion, the first bonding pad portion and the second bonding pad portion are respectively over the first surface and the second surface. The chip package structure includes a second chip structure over the heat-spreading substrate. The second chip structure is electrically connected to the first chip structure through the conductive plug structure, the first thermal conductivity of the substrate is higher than a third thermal conductivity of the second chip structure, and the heat-spreading substrate contacts with the first chip structure and the second chip structure.

In accordance with some embodiments, a chip package structure is provided. The chip package structure includes a first chip structure. The chip package structure includes a first heat-spreading substrate on and directly bonded with the first chip structure. The first heat-spreading substrate includes a substrate and a conductive plug structure, a first thermal conductivity of the substrate is higher than a second thermal conductivity of the first chip structure, the substrate has a first surface and a second surface, the conductive plug structure has a first bonding pad portion, a second bonding pad portion, and a via portion, the first bonding pad portion and the second bonding pad portion are respectively over the first surface and the second surface. The chip package structure includes a conductive bump under and bonded to the first chip structure.

In accordance with some embodiments, a method for forming a chip package structure is provided. The method includes forming a first heat-spreading substrate. The first heat-spreading substrate includes a substrate and a conductive plug structure, the substrate has a first surface and a second surface, the conductive plug structure has a first bonding pad portion, a second bonding pad portion, and a via portion, and the first bonding pad portion and the second bonding pad portion are respectively over the first surface and the second surface. The method includes bonding the first heat-spreading substrate onto a first chip structure. A first thermal conductivity of the substrate is higher than a second thermal conductivity of the first chip structure. The method includes bonding a second chip structure onto the first heat-spreading substrate. The second chip structure is electrically connected to the first chip structure through the conductive plug structure, the first thermal conductivity of the substrate is higher than a third thermal conductivity of the second chip structure, and the first heat-spreading substrate contacts with the first chip structure and the second chip structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A chip package structure, comprising:
a first chip structure;
a heat-spreading substrate over the first chip structure, wherein:
the heat-spreading substrate comprises a substrate and a conductive plug structure, a first thermal conductivity of the substrate is higher than a second thermal conductivity of the first chip structure, the substrate has a first surface and a second surface, the conductive plug structure has a first bonding pad portion, a second bonding pad portion, and a via portion, and the first bonding pad portion and the second bonding pad portion are respectively over the first surface and the second surface; and
a second chip structure over the heat-spreading substrate, wherein the second chip structure is electrically connected to the first chip structure through the conductive plug structure, the first thermal conductivity of the substrate is higher than a third thermal conductivity of the second chip structure, and the heat-spreading substrate contacts with the first chip structure and the second chip structure.

2. The chip package structure as claimed in claim 1, wherein the substrate of the heat-spreading substrate is made of a dielectric material.

3. The chip package structure as claimed in claim 1, wherein the heat-spreading substrate further comprises a first bonding layer over the first surface of the substrate, the first bonding layer is in direct contact with the first chip structure, and the first bonding pad portion passes through the first bonding layer.

4. The chip package structure as claimed in claim 3, wherein the first thermal conductivity of the substrate is higher than a fourth thermal conductivity of the first bonding layer.

5. The chip package structure as claimed in claim 3, wherein the heat-spreading substrate further comprises a second bonding layer over the second surface of the substrate, the second bonding layer is in direct contact with the second chip structure, and the second bonding pad portion passes through the second bonding layer.

6. The chip package structure as claimed in claim 5, wherein the heat-spreading substrate further comprises a first planarization layer between the first bonding layer and the substrate, and a third surface of the first planarization layer faces away from the substrate and is more planar than the first surface of the substrate.

7. The chip package structure as claimed in claim 6, wherein the heat-spreading substrate further comprises a second planarization layer between the second bonding layer and the substrate, and a fourth surface of the second planarization layer faces away from the substrate and is more planar than the second surface of the substrate.

8. The chip package structure as claimed in claim 1, wherein the via portion passes through the substrate and is narrower than both the first bonding pad portion and the second bonding pad portion.

9. A chip package structure, comprising:
a first chip structure;
a first heat-spreading substrate on and bonded with the first chip structure, wherein:
the first heat-spreading substrate comprises a substrate and a conductive plug structure, a first thermal conductivity of the substrate is higher than a second thermal conductivity of the first chip structure, the substrate has a first surface and a second surface, the conductive plug structure has a first bonding pad portion, a second bonding pad portion, and a via portion, the first bonding pad portion and the second bonding pad portion are respectively over the first surface and the second surface; and
a conductive bump under and bonded to the first chip structure.

10. The chip package structure as claimed in claim 9, further comprising:
a second chip structure over the heat-spreading substrate, wherein the second chip structure is electrically connected to the first chip structure through the conductive plug structure, the first thermal conductivity of the substrate is higher than a third thermal conductivity of the second chip structure, and the heat-spreading substrate is in direct contact with the second chip structure; and
a second heat-spreading substrate over the second chip structure, wherein a fourth thermal conductivity of the second heat-spreading substrate is higher than the third thermal conductivity of the second chip structure.

11. The chip package structure as claimed in claim 10, wherein the first heat-spreading substrate is thicker than the second heat-spreading substrate.

12. The chip package structure as claimed in claim 10, wherein the first chip structure has a first conductive bonding pad, the first conductive bonding pad is directly bonded with the first bonding pad portion of the first heat-spreading substrate, and the first bonding pad portion is wider than the first conductive bonding pad.

13. The chip package structure as claimed in claim 12, wherein the second chip structure has a second conductive bonding pad, the second conductive bonding pad is directly bonded with the second bonding pad portion of the first heat-spreading substrate, and the second bonding pad portion is wider than the second conductive bonding pad.

14. The chip package structure as claimed in claim 10, wherein the first chip structure has a first conductive bonding pad, the first conductive bonding pad is directly bonded with the first bonding pad portion of the first heat-spreading substrate, and the first conductive bonding pad is wider than the first bonding pad portion.

15. A chip package structure, comprising:
a heat-spreading substrate, wherein the heat-spreading substrate has a substrate with a first surface and a second surface opposite to the first surface, a conductive plug structure penetrating through the substrate, a first bonding layer over the first surface of the substrate, and a second bonding layer over the second surface of the substrate, wherein the conductive plug structure has a first bonding pad portion protruding from the first surface of the substrate and embedded in the first bonding layer, and the conductive plug structure has a second bonding pad portion protruding from the second surface of the substrate and embedded in the second bonding layer;
a first chip structure bonded to the first bonding layer and the first bonding pad portion, wherein a first thermal conductivity of the substrate is higher than a second thermal conductivity of the first chip structure; and
a second chip structure bonded to the second bonding layer and the second bonding pad portion, wherein the first thermal conductivity of the substrate is higher than a third thermal conductivity of the second chip structure.

16. The chip package structure as claimed in claim 15, wherein a first interface between the first bonding layer and the first chip structure meets a second interface between the first bonding pad portion and the first chip structure.

17. The chip package structure as claimed in claim 16, wherein a third interface between the second bonding layer and the second chip structure meets a fourth interface between the second bonding pad portion and the second chip structure.

18. The chip package structure as claimed in claim 15, further comprising:
a second heat-spreading substrate over the second chip structure, wherein the second chip structure is between the heat-spreading substrate and the second heat-spreading substrate; and
a third chip structure over the second heat-spreading substrate, wherein the second heat-spreading substrate is between the third chip structure and the second chip structure.

19. The chip package structure as claimed in claim 18, wherein the second heat-spreading substrate is thicker than the heat-spreading substrate.

20. The chip package structure as claimed in claim 18, wherein the second heat-spreading substrate is substantially as wide as the heat-spreading substrate.
